(19) United States
(12) Patent Application Publication
(10) Pub. No.: US 2026/0256013 A1
(43) Pub. Date: Aug. 27, 2026

(54) METHOD OF MANUFACTURING ELECTRONIC DEVICE

(71) Applicant: Advanced Semiconductor Engineering, Inc., Kaohsiung (TW)

(72) Inventors: Ping-Feng YANG, Kaohsiung (TW); Chia-Hao SUNG, Kaohsiung (TW); Chao-Hung WENG, Kaohsiung (TW); Chun Hung TSAI, Kaohsiung (TW); Kuan-Lin YEH, Kaohsiung (TW); Shang HSU, Kaohsiung (TW); Pei-Chin HUANG, Kaohsiung (TW); Ling-Hua Wang, Kaohsiung (TW)

(73) Assignee: Advanced Semiconductor Engineering, Inc., Kaohsiung (TW)

(21) Appl. No.: 19/064,662

(22) Filed: Feb. 26, 2025

(51) Int. Cl. H01L 21/56; H01L 21/78; H01L 23/00

(52) U.S. Cl. CPC H10W 74/014; H10P 54/00; H10W 74/019; H10W 72/0198

(57) ABSTRACT

The present disclosure provides a method of manufacturing an electronic device. The method includes providing a panel assembly including a plurality of first electronic components, dividing the panel assembly into a plurality of strips, forming a first encapsulant over one of the plurality of strips, and dividing the one of the plurality of strips into a plurality of electronic devices.

### BACKGROUND

### 1. Technical Field

The present disclosure relates to a method of manufacturing an electronic device.

### 2. Description of the Related Art

Multiple-die packaging solutions, such as System in Package (SiP) and Package on Package (PoP), are increasingly utilized to address the demand for higher die and component density. In one configuration, a memory die (e.g., DRAM) is stacked atop a logic die (e.g., ASIC), with interconnections made via copper pillars, wire bonds, or through-silicon vias. While larger panel assemblies can enhance units per hour (UPH), they may also face challenges such as uneven heating during processing and increased mechanical stress, leading to significant warpage issues.

### SUMMARY

In some arrangements, a method of manufacturing an electronic device includes providing a panel assembly including a plurality of first electronic components, dividing the panel assembly into a plurality of strips, forming a first encapsulant over one of the plurality of strips, and dividing the one of the plurality of strips into a plurality of electronic devices.

In some arrangements, a method of manufacturing an electronic device includes providing a first electronic component, forming an interconnection structure over the first electronic component, forming a cutting area adjacent to the interconnection structure, and forming a first encapsulant over the cutting area.

In some arrangements, a method of manufacturing an electronic device includes providing a panel assembly including a plurality of first electronic components, obtaining at least one strip from the panel assembly for warpage control, forming a first encapsulant over the at least one strip, and obtaining at least one electronic device from the at least one strip.

### BRIEF DESCRIPTION OF THE DRAWINGS

Aspects of some arrangements of the present disclosure are best understood from the following detailed description when read with the accompanying figures. It is noted that various structures may not be drawn to scale, and dimensions of the various structures may be arbitrarily increased or reduced for clarity of discussion.

FIG. 1 illustrates a cross-sectional view of an electronic device in accordance with some arrangements of the present disclosure.

FIG. 2 illustrates a cross-sectional view of an electronic device in accordance with some arrangements of the present disclosure.

FIG. 3A, FIG. 3B, FIG. 3C, FIG. 3D, FIG. 3E, FIG. 3F, FIG. 3G, FIG. 3H, FIG. 3I, FIG. 3J, FIG. 3K, FIG. 3L, FIG. 3M, and FIG. 3N illustrate cross-sectional views in one or more stages of a method of manufacturing an electronic device in accordance with an embodiment of the present disclosure.

FIG. 3A′, FIG. 3B′, FIG. 3E′, FIG. 3I′, and FIG. 3N′ illustrate top views in one or more stages of a method of manufacturing an electronic device in accordance with an embodiment of the present disclosure.

### DETAILED DESCRIPTION

The following disclosure provides for many different arrangements, or examples, for implementing different features of the provided subject matter. Specific examples of components and arrangements are described as follows to explain certain aspects of the present disclosure. These are, of course, merely examples and are not intended to be limiting. For example, the formation of a first feature over or on a second feature in the description that follows may include arrangements in which the first and second features are formed or disposed in direct contact, and may also include arrangements in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various arrangements and/or configurations discussed.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of arrangements of this disclosure are not deviated from by such arrangement.

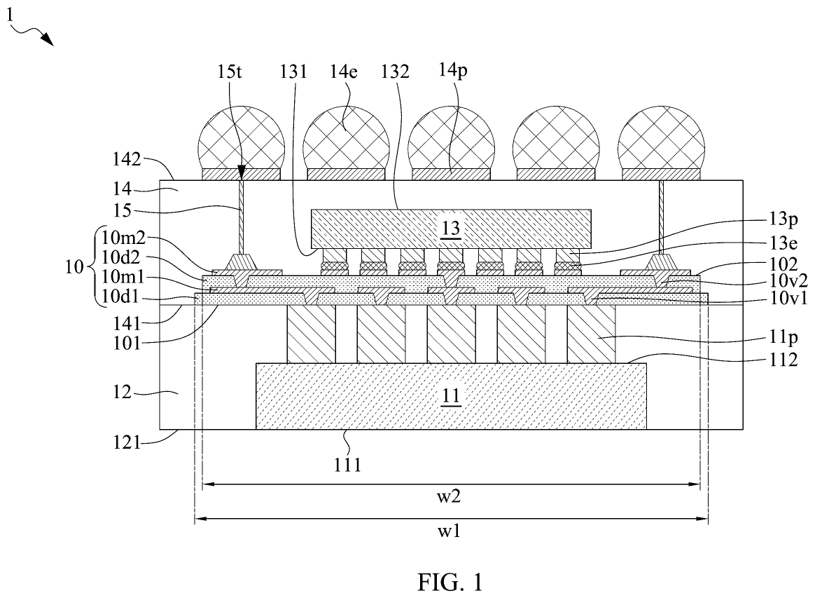

FIG. 1 illustrates a cross-sectional view of an electronic device 1 in accordance with some arrangements of the present disclosure. In some arrangements, the electronic device 1 may include a package, such as a semiconductor device package. In some arrangements, the electronic device 1 may include a carrier 10, electronic components 11, 13, encapsulants 12, 14, and a connection element 15.

In some arrangements, the carrier 10 may include an interconnection structure or a circuit structure. The circuit structure may include a redistribution layer (RDL), a circuit layer, a conductive pillar, conductive pad, conductive trace, a conductive via, a conductive wire, or other conductive elements. The circuit structure may provide electrical connections for the components connected with the carrier 10.

The carrier 10 may include a surface 101 and a surface 102 opposite to the surface 101. The carrier 10 may include dielectrics 10d1, 10d2 and metals 10m1, 10m2. The dielectric 10d1 may be or constitute a part of the surface 101. The metal 10m1 may be disposed over the dielectric 10d1, and may connect with a conductive via 10v1 penetrating the dielectric 10d1. The conductive via 10v1 may be at least partially exposed on the surface 101.

The dielectric 10d2 may be disposed over the dielectric 10d1 to cover the metal 10m1. A dimension (such as a width or a length) w1 of the dielectric 10d1 may be substantially greater than a dimension (such as a width or a length) w2 of the dielectric 10d2. For example, a side of the dielectric 10d2 may be recessed with respect to a side of the dielectric 10d1. For example, a side of the dielectric 10d2 may be set back in relation to a side of the dielectric 10d1. For example, a periphery portion of the dielectric 10d2 may be exposed from the dielectric 10d1. For example, the dielectric 10d2 and the dielectric 10d1 may include or define a stepped structure, a tiered structure, or a terraced structure.

The metal 10m2 may be disposed over the dielectric 10d2, and may connect with a conductive via 10v2 penetrating the dielectric 10d2. The metal 10m2 may include one or more conductive pads in proximity to, adjacent to, or embedded in and exposed by the surface 102. The carrier 10 may include a solder resist on the surface 102 to fully expose or expose at least a portion of the conductive pads for electrical connections.

The metal 10m1 and the metal 10m2 may each include a conductive element, such as a conductive pillar, conductive pad, conductive trace, a conductive via, a conductive wire, or another feasible conductive element. Examples of the conductive material include gold (Au), silver (Ag), aluminum (Al), copper (Cu), platinum (Pt), palladium (Pd), other metal(s) or alloy(s), or a combination thereof.

The dielectric 10d1 and the dielectric 10d2 may each include, for example, phosphoric anhydride (PA), a polyimide (PI), a polybenzoxazole (PBO), Borophosphosilicate Glass (BPSG), Undoped Silicate Glass (USG), silicon oxide, silicon nitride, silicon oxynitride, any combination of two or more thereof, or the like.

The electronic components 11 and 13 may each include an active device or an active component. In some arrangements, the electronic components 11 and 13 may each be or include circuits or circuit elements that rely on an external power supply to control or modify electrical signals. Examples of the active device may include a chip or a die including a semiconductor substrate, one or more integrated circuit devices and one or more overlying interconnection structures therein.

In some arrangements, the electronic component 11 may include a non-volatile memory (such as a flash memory and a read-only memory (ROM)) or a volatile memory (such as a Dynamic Random Access Memory (DRAM)). In some arrangements, the electronic component 11 may include a high bandwidth memory (HBM). The electronic component 11 may include a single chip or a plurality of chips. In some arrangements, the electronic component 13 may include a controller, a processor, a central processing unit (CPU), a field-programmable gate array (FPGA), an application specific integrated circuit (ASIC), etc. The electronic component 13 may include a single chip or a plurality of chips.

The electronic component 11 may be disposed under the carrier 10. The electronic component 11 may be disposed over the surface 101 of the carrier 10. The electronic component 11 may be separated from the electronic component 13 by the carrier 10. The electronic component 11 and the electronic component 13 may be disposed on opposite sides of the carrier 10. The electronic component 11, the electronic component 13, and the carrier 10 may be at least partially overlapped in a direction (such as a vertical direction) substantially perpendicular to the surface 101 and/or the surface 102 of the carrier 10.

The electronic component 11 may be electrically connected to one or more other electrical components (if any) and to the carrier 10, and the electrical connections may be attained by way of flip-chip or wire-bond techniques.

In some arrangements, the electronic component 11 may include a surface 112 facing the carrier 10 and a surface 111 opposite to the surface 112. The surface 112 may include an active surface and the surface 111 may include a backside surface. In some arrangements, the electronic component 11 may include a conductive pad 11p adjacent to the surface 112 for providing electrical connections between the electronic device 11 and the carrier 10. The conductive pad 11p may be electrically connected with the conductive via 10v1 exposed on the surface 101 of the carrier 10. The conductive pad 11p may directly contact the conductive via 10v1 exposed on the surface 101 of the carrier 10.

The electronic component 13 may be disposed over the carrier 10. The electronic component 13 may be disposed over the surface 102 of the carrier 10. The electronic component 13 may be electrically connected to one or more other electrical components (if any) and to the carrier 10, and the electrical connections may be attained by way of flip-chip (such as by utilizing the electrical contact 13e) or wire-bond techniques.

In some arrangements, the electronic component 13 may include a surface 131 facing the carrier 10 and a surface 132 opposite to the surface 132. The surface 131 may include an active surface and the surface 132 may include a backside surface. In some arrangements, the electronic component 13 may include a conductive pad 13p adjacent to the surface 132 for providing electrical connections between the electronic device 13 and the carrier 10.

The positions, functions, and number of electronic components in the electronic device 1 are not intended to limit the present disclosure. For example, there may be any number of electronic components in the electronic device 1 due to design requirements. For example, the electronic component 13 may be replaced with a passive component.

The encapsulant 12 may be disposed over the surface 101 of the carrier 10. The encapsulant 12 may contact (such as directly contact) the surface 101 of the carrier 10. The encapsulant 12 may cover, surround, or encapsulate the electronic component 11. The surface 111 of the electronic component 11 may be exposed from the encapsulant 12. The encapsulant 12 may include a surface 121 facing away from the carrier 10. The surface 121 of the encapsulant 12 and the surface 111 of the electronic component 11 may be substantially aligned or coplanar.

The encapsulant 12 may be disposed between the surface 101 of the carrier 10 and the surface 112 of the electronic component 11. The encapsulant 12 may cover, surround, or encapsulate the conductive pad 11p of the electronic component 11. The conductive pad 11p of the electronic component 11 may be at least partially exposed by the encapsulant 12.

The encapsulant 14 may be disposed over the encapsulant 12 to cover the carrier 10. The carrier 10 may be embedded in the encapsulant 14 and the encapsulant 12. The encapsulant 14 may contact (such as directly contact) the encapsulant 12 exposed by the carrier 10.

The encapsulant 14 may be disposed over the surface 102 of the carrier 10. The encapsulant 14 may contact (such as directly contact) the surface 102 of the carrier 10. The encapsulant 14 may cover, surround, or encapsulate the carrier 10. The encapsulant 14 may cover, surround, or encapsulate the stepped structure of the carrier 10.

The encapsulant 14 may cover, surround, or encapsulate the electronic component 13. The surface 132 of the electronic component 13 may be covered by the encapsulant 14. The encapsulant 14 may cover, surround, or encapsulate the connection element 15.

The encapsulant 14 may include a surface 141 and a surface 142 opposite to the surface 141. The surface 141 of the encapsulant 14 may contact (such as directly contact) the encapsulant 12. The surface 141 of the encapsulant 14 may be substantially aligned or coplanar with the surface 101 of the carrier 10. In some arrangements, an interface or an intersurface labeled “141” of the encapsulant 14 and the encapsulant 12 may be substantially aligned or coplanar with the surface 101 of the carrier 10.

The surface 142 of the encapsulant 14 may face away from the carrier 10. In some arrangements, the surface 142 of the encapsulant 14 may be the farthest surface from the carrier 10.

The encapsulant 14 may be disposed between the surface 102 of the carrier 10 and the surface 131 of the electronic component 13. The encapsulant 14 may cover, surround, or encapsulate the conductive pad 13p of the electronic component 13 and the electrical contact 13e.

In some arrangements, the encapsulant 12 and the encapsulant 14 may each include an epoxy resin having fillers, a molding compound (e.g., an epoxy molding compound or other molding compound), a polyimide, a phenolic compound or material, a material with a silicone dispersed therein, or a combination thereof.

In some arrangements, a conductive pad 14p and an electrical contact 14e may be disposed over the surface 142 of the encapsulant 14 for providing electrical connections between the electronic device 1 and an external device (e.g., a PCB, another electronic device, an electronic module, and so on).

In some arrangements, the electrical contacts 13e and 14e may each include a reflowable conductive material, such as a soldering material. In some arrangements, the electrical contacts 13e and 14e may each include one or more solder balls or solder bumps, such as a controlled collapse chip connection (C4) bump, a ball grid array (BGA) or a land grid array (LGA).

The connection element 15 may be disposed over the carrier 10 and electrically connected to the carrier 10. The connection element 15 may be electrically connected between the carrier 10 and the electrical contact 14e. The connection element 15 may at least partially penetrate the encapsulant 14.

In some arrangements, the carrier 10, the electronic component 11, the electronic component 13, and the electrical contact 14e may each be electrically connected, and the electrical connections may be attained by the connection element 15. For example, the connection element 15 may provide, constitute, or establish signal transmission paths among the carrier 10, the electronic component 11, the electronic component 13, and the electrical contact 14e.

The connection element 15 may include conductive wires. However, in some arrangements, the connection element 15 may include conductors of other shapes or configurations, such as wire bundles, cables, metal blocks, solder balls, pillars, rods, rails, pipes, etc. In some arrangements, the connection element 15 may include conductive material such as metal or a metal alloy. Examples of the conductive material include gold (Au), silver (Ag), aluminum (Al), copper (Cu), platinum (Pt), palladium (Pd), other metal(s) or alloy(s), or a combination of two or more thereof.

In some arrangements, an end 15t of the connection element 15 may contact (such as directly contact) the conductive pad 14p. For example, the end 15t of the connection element 15 may be exposed from the encapsulant 14 and contacted by the conductive pad 14p.

In some arrangements, a roughness of the surface 142 of the encapsulant 14 and a roughness of the surface 121 of the encapsulant 12 may be different. For example, a roughness of the surface 142 of the encapsulant 14 may be substantially smaller than a roughness of the surface 121 of the encapsulant 12. For example, a roughness of the surface 121 of the encapsulant 12 may be substantially greater than a roughness of the surface 142 of the encapsulant 14.

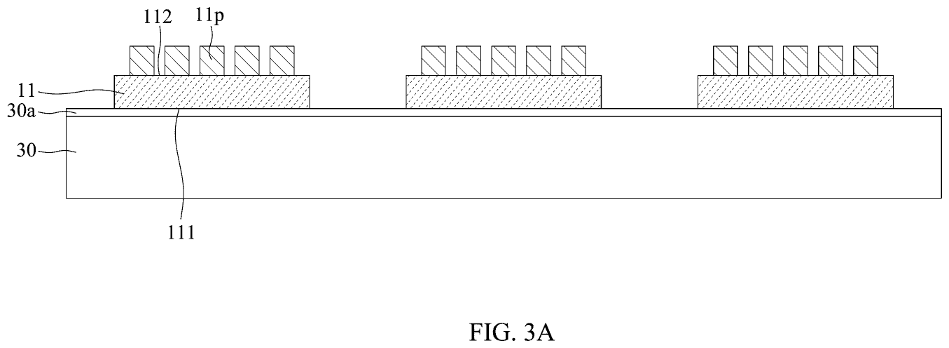

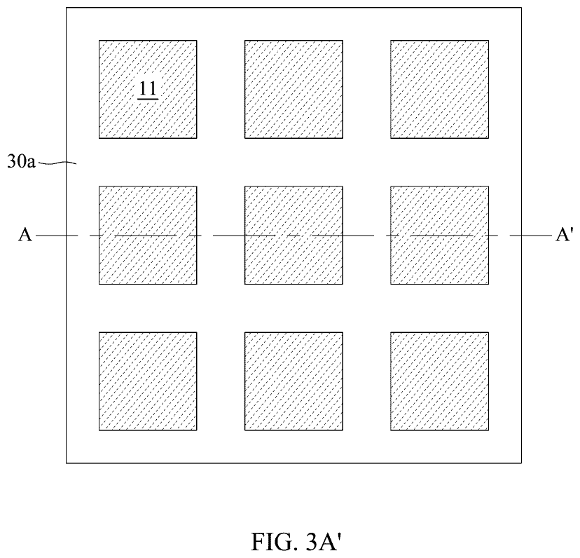

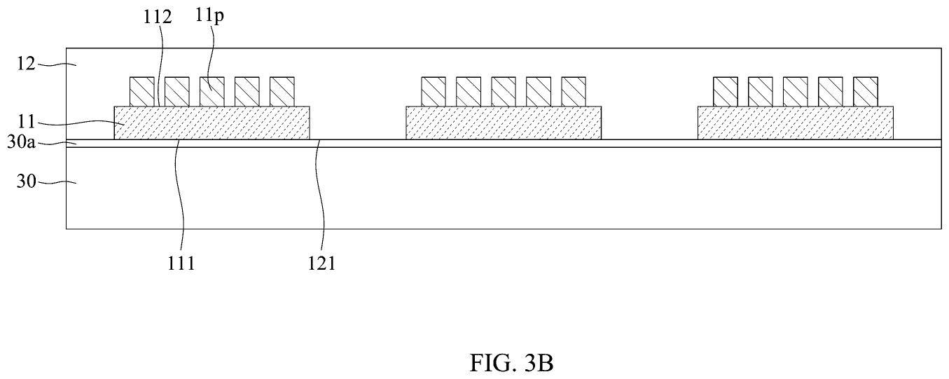

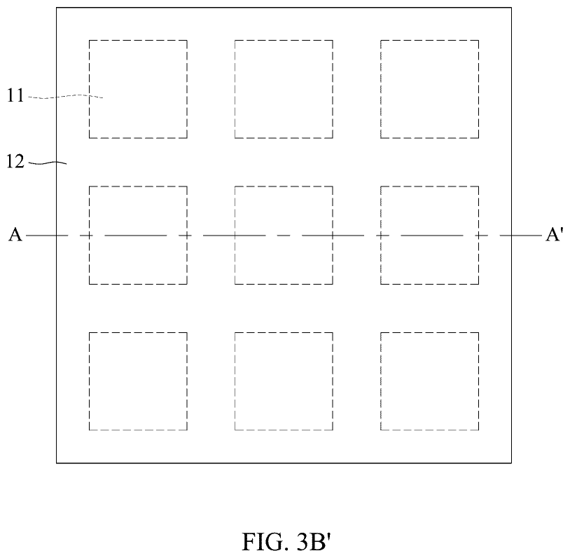

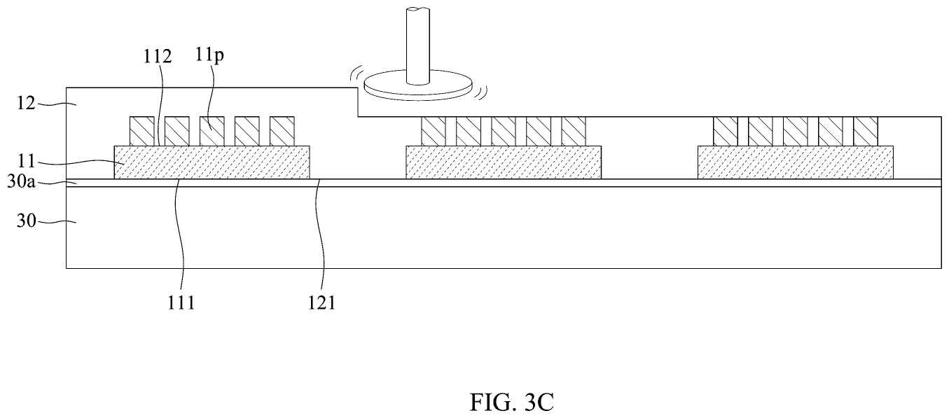

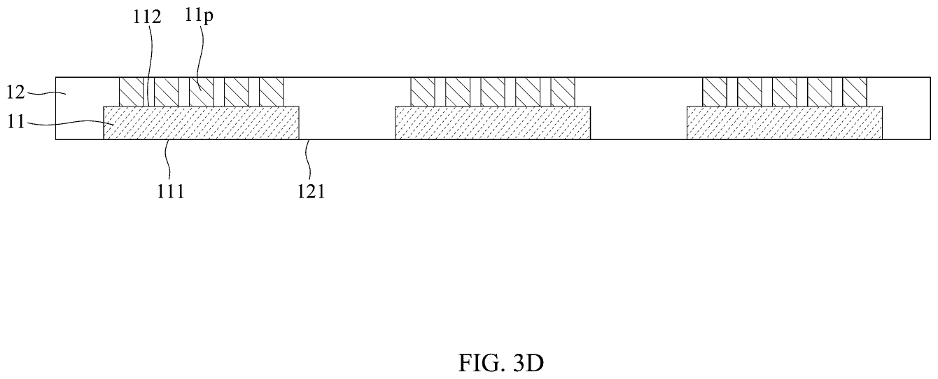

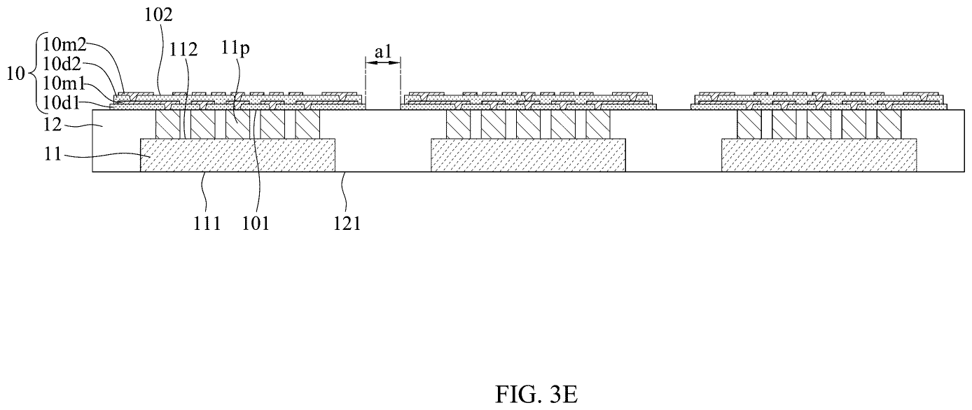

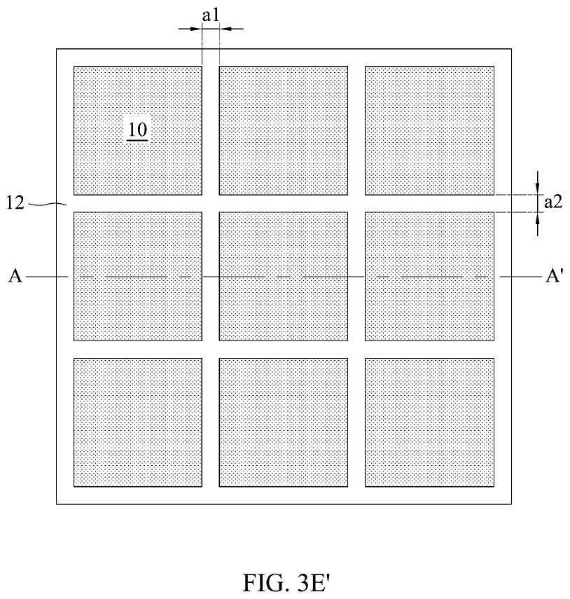

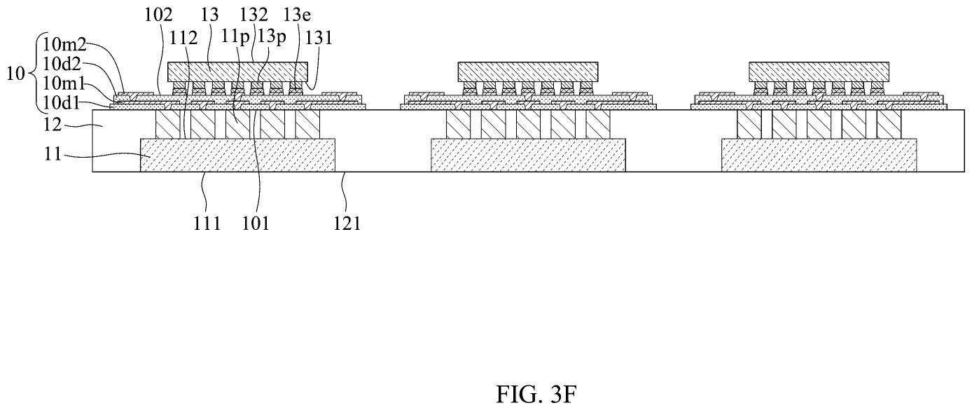

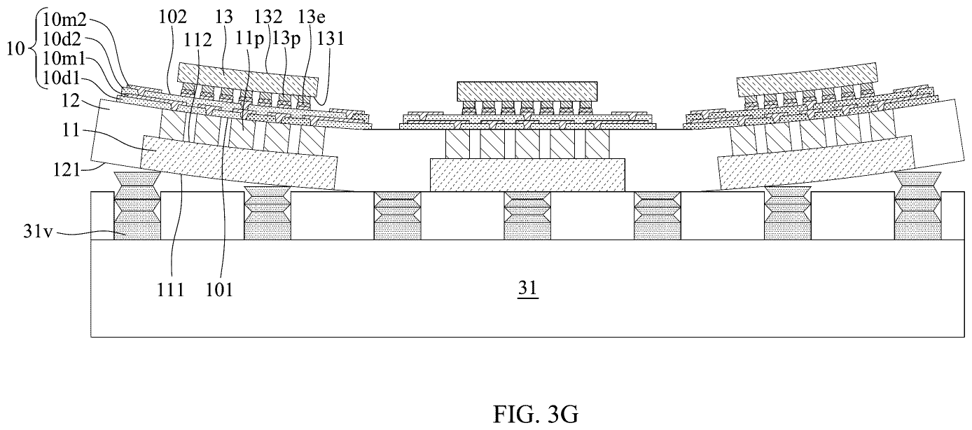

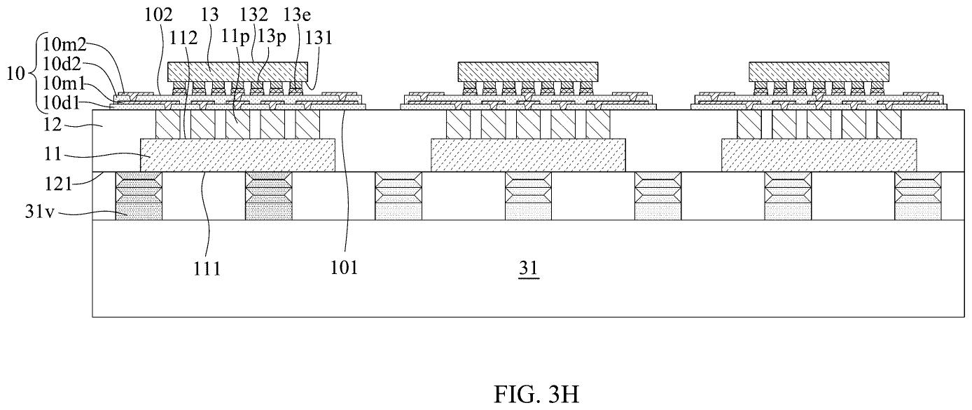

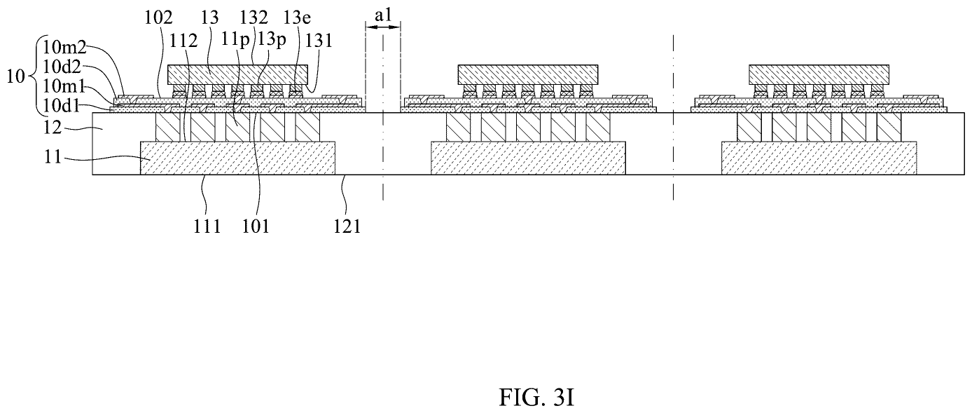

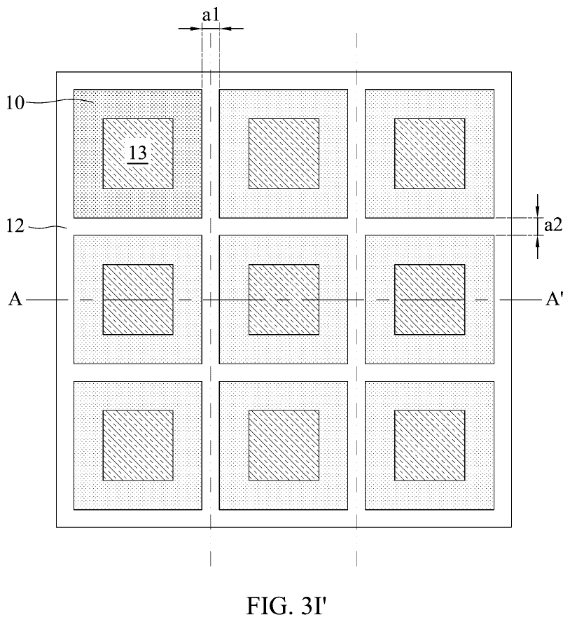

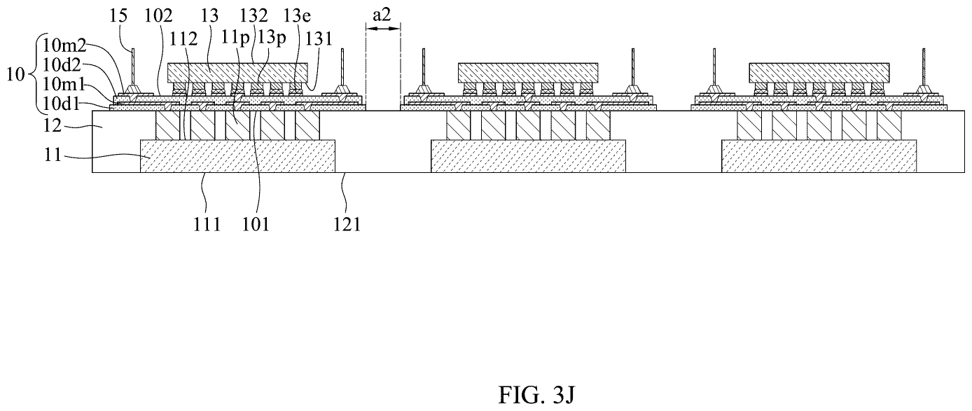

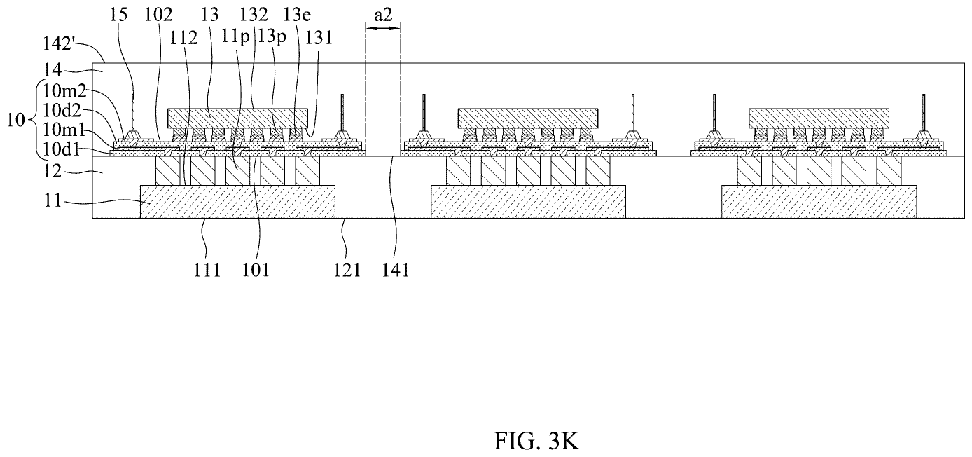

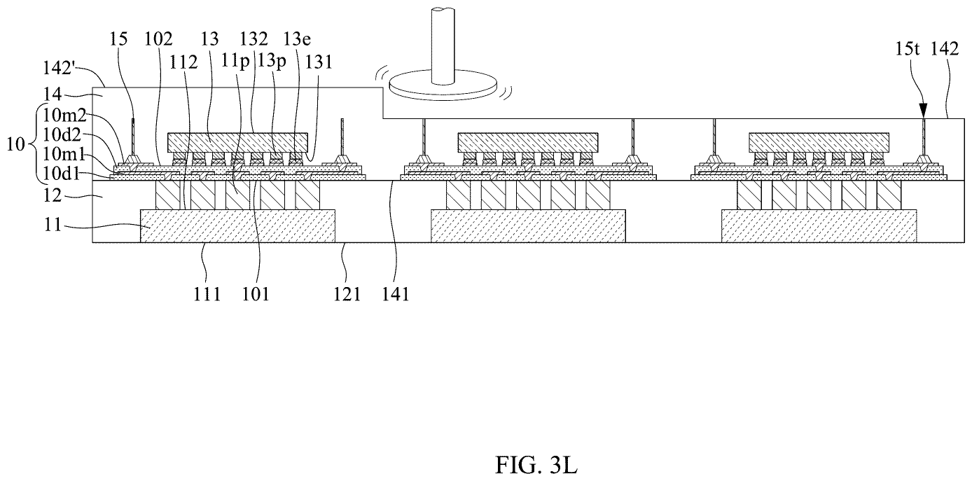

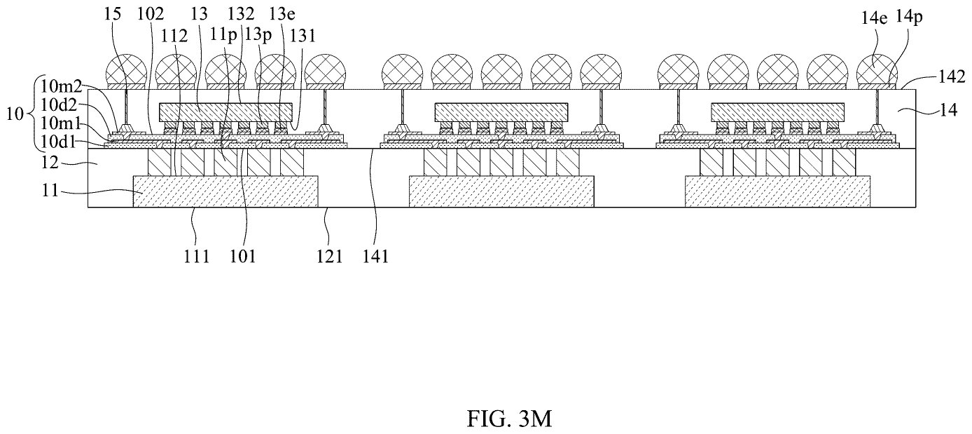

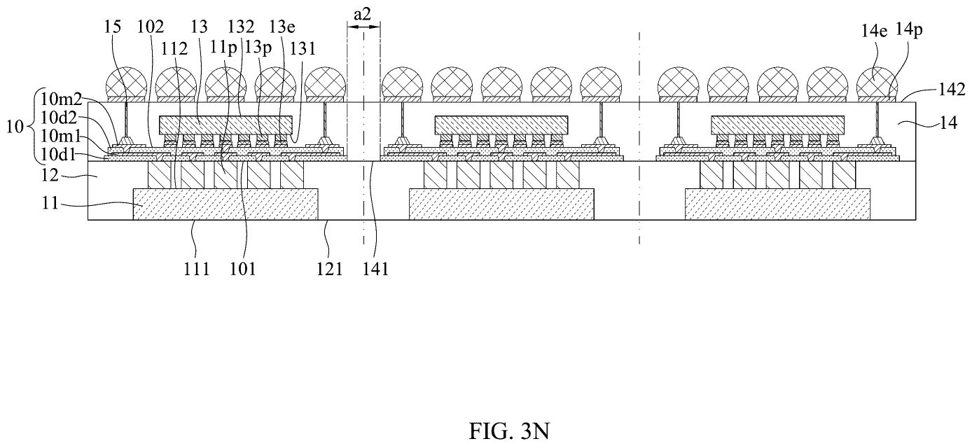

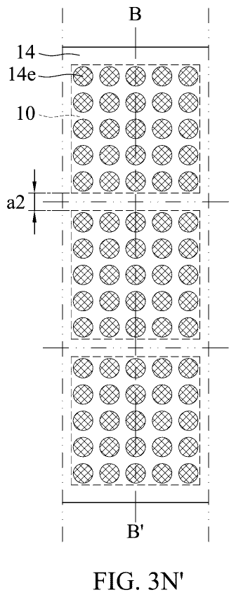

During a manufacturing process of the electronic device 1 according to some embodiments of the present disclosure, the surface 142 of the encapsulant 14 may be subject to a planarization operation or a grinding operation (such as the operation in FIG. 3L) while the surface 121 of the encapsulant 12 is not. After the operation, the roughness values of the surface 142 and the surface 121 may be different.

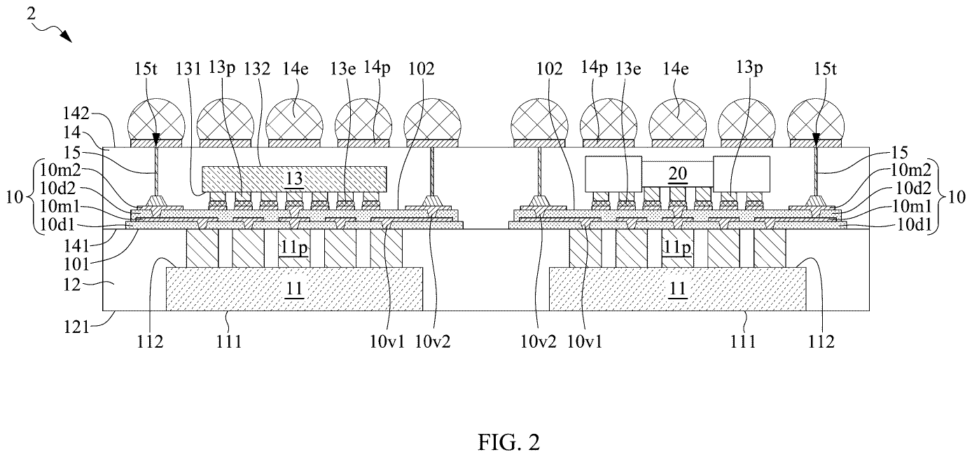

FIG. 2 illustrates a cross-sectional view of an electronic device 2 in accordance with some arrangements of the present disclosure. The electronic device 2 in FIG. 2 is similar to the electronic device 1 in FIG. 1 except that the electronic device 2 further includes an electronic component 20.

In some arrangements, the electronic device 2 may include a system-in-package (SiP) module. The electronic device 2 may include two electronic devices 1, and one of the electronic components 13 is replaced with an electronic component 20.

The electronic component 20 may include a passive component or a passive device. In some arrangements, the electronic component 20 may contain circuits or circuit elements that do not need an external power source to function and do not provide electrical gain. Examples of the passive device may include an inductance device (or an inductor), a capacitance device (or capacitor), a resistor, a diode, a fuse, an antifuse, etc.

The positions, functions, and number of electronic components in the electronic device 2 are not intended to limit the present disclosure. For example, there may be any number of electronic components in the electronic device 2 due to design requirements. For example, the electronic component 20 may be replaced with an active component.

FIG. 3A, FIG. 3B, FIG. 3C, FIG. 3D, FIG. 3E, FIG. 3F, FIG. 3G, FIG. 3H, FIG. 3I, FIG. 3J, FIG. 3K, FIG. 3L, FIG. 3M, and FIG. 3N illustrate cross-sectional views in one or more stages of a method of manufacturing an electronic device in accordance with an embodiment of the present disclosure. At least some of these figures have been simplified to better understand the aspects of the present disclosure. In some arrangements, the electronic device 1 may be manufactured through the steps illustrated in FIG. 3A, FIG. 3B, FIG. 3C, FIG. 3D, FIG. 3E, FIG. 3F, FIG. 3G, FIG. 3H, FIG. 3I, FIG. 3J, FIG. 3K, FIG. 3L, FIG. 3M, and FIG. 3N.

Referring to FIG. 3A, a temporary carrier 30 may be provided (e.g., manufactured). The temporary carrier 30 may include temporary or base material such as silicon, polymer, polymer composite, metal, ceramic, glass, glass epoxy, beryllium oxide, or other suitable low-cost, rigid materials or bulk semiconductor materials for structural support. In some arrangements, the area of the temporary carrier 30 may be approximately 600 square millimeters.

The electronic component 11 may include the surface 111 facing the temporary carrier 30 and the surface 112 opposite to the surface 111. One or more electronic components 11 may be disposed over the temporary carrier 30. The surface 111 (such as the backside surface) of the electronic component 11 may be connected to the temporary carrier 30. The electronic component 11 may include the conductive pads 11p adjacent to the surface 112 (such as the active surface).

The electronic component 11 may be connected to the temporary carrier 30 through an adhesive layer 30a. The adhesive layer 30a may include a die attach film (DAF), a glue, a bonding layer, an underfill, or another suitable material. The adhesive layer 30a may cover the upper surface of the temporary carrier 30. For example, a portion of the adhesive layer 30a may be covered by the electronic components 11, while another portion may be exposed among the electronic components 11.

FIG. 3A′ illustrates a top view of the structure shown in FIG. 3A. In some arrangements, FIG. 3A provides a cross-sectional view of the structure cut along the line AA′ in FIG. 3A′.

In some arrangements, the electronic components 11 may be organized or arranged in an M×N array, where M and N are positive integers that can be equal or different.

The M×N array configuration can facilitate the subsequent singulation operation (such as the operation in FIG. 3I) that separates the electronic components 11 into strips. For example, M strips may be obtained, with each strip containing N electronic components 11. Alternatively, N strips may be obtained, with each strip containing M electronic components 11.

Referring to FIG. 3B, the encapsulant 12 may be disposed over temporary carrier 30 to cover the one or more electronic components 11. The encapsulant 12 may cover, surround, or encapsulate the electronic component 11. The encapsulant 12 may cover, surround, or encapsulate the conductive pad 11p of the electronic component 11.

The surface 121 of the encapsulant 12 and the surface 111 of the electronic component 11 may be substantially aligned or coplanar. The surface 121 of the encapsulant 12 may be connected to the temporary carrier 30 through the adhesive layer 30a.

In some arrangements, the encapsulant 12 may be formed by molding, such as by printing, compression molding, transfer molding, liquid encapsulant molding, vacuum lamination, spin coating, or other suitable processes.

FIG. 3B′ illustrates a top view of the structure shown in FIG. 3B. In some arrangements, FIG. 3B provides a cross-sectional view of the structure cut along the line AA′ in FIG. 3B′. In some arrangements, the electronic components 11 are under the encapsulant 12 and illustrated by dashed lines.

In some arrangements, the operation shown in FIGS. 3B and 3B′ may be referred to as a first molding operation. The structure obtained from the operation shown in FIGS. 3B and 3B′ may be a panel assembly. The panel assembly may include one or more electronic components 11 embedded, covered, or encapsulated in the encapsulant 12. In some arrangements, the area of the panel assembly may be approximately 600 square millimeters.

Referring to FIG. 3C, a planarization operation or a grinding operation may be performed to remove a portion of the encapsulant 12 to expose the conductive pad 11p of the electronic components 11. The planarization operation or grinding operation may include an abrasive machining process that uses a grinding wheel or grinder, a chemical mechanical planarization (CMP) process, an etching process, or a laser direct ablation (LDA) process.

Referring to FIG. 3D, the temporary carrier 30 and the adhesive layer 30a may be removed from the electronic component 11 and the encapsulant 12. The surface 111 of the electronic component 11 and the surface 121 of the encapsulant 12 may be exposed. The surface 111 of the electronic component 11 and the surface 121 of the encapsulant 12 may be substantially aligned or coplanar.

Referring to FIG. 3E, one or more carriers 10 may be disposed, provided, or formed over the electronic component 11 and the encapsulant 12. In some arrangements, the carrier 10 may be formed through operations of electroplating, molding, and grinding. The operations of electroplating, molding, and grinding may be repeated according to the number of layers in the carrier 10. For example, the carrier 10 may include dielectrics 10d1 and 10d2, and metals 10m1 and 10m2. The surface 101 of the carrier 10 may contact (such as directly contact) the encapsulant 12.

In some arrangements, the carriers 10 may be disposed according to the locations of the electronic devices 11. For example, the conductive via (such as the conductive via 10v1 in FIG. 1) of the carrier 10 may be electrically connected with the conductive pad 11p of the electronic device 11.

A side of the dielectric 10d2 may be recessed with respect to a side of the dielectric 10d1. For example, a side of the dielectric 10d2 may be set back in relation to a side of the dielectric 10d1. For example, the dielectric 10d2 and the dielectric 10d1 may include or define a stepped structure, a tiered structure, or a terraced structure.

In some arrangements, the carriers 10 may include multiple separated carriers. For example, the carriers 10 may not physically contact or be connected to one another. For example, the carriers 10 may be spaced apart by a distance a1. For example, a portion of the encapsulant 12 may be covered by the carriers 10, while another portion may be exposed among the carriers 10.

In some arrangements, the carriers 10 may be spaced apart by a cutting area or a scribe line. For example, a portion of the encapsulant 12 exposed by the carriers 10 may include a cutting area or be configured to function as a cutting area. For example, the encapsulant 12 in the cutting area may be exposed among the carriers 10.

FIG. 3E′ illustrates a top view of the structure shown in FIG. 3E. In some arrangements, FIG. 3E provides a cross-sectional view of the structure cut along the line AA′ in FIG. 3E′.

The carriers 10 may be organized or arranged in an M×N array, where M and N are positive integers that may be substantially equal or different.

The M×N array configuration can facilitate the subsequent singulation operation (such as the operation in FIG. 3I) that separates the carriers 10 into strips. For example, M strips may be obtained, with each strip containing N carriers 10. Alternatively, N strips may be obtained, with each strip containing M carriers 10.

In some arrangements, the carriers 10 in the adjacent columns are spaced apart by the distance a1. The carriers 10 in the same column are spaced apart by a distance a2. The distance a1 and the distance a2 may be substantially equal or different. In some arrangements, the carriers 10 may be spaced apart by a cutting area. For example, the distances a1 and a2 may represent the dimensions of the cutting area.

Referring to FIG. 3F, one or more electronic components 13 may be disposed over the carrier 10. The electronic component 13 may be disposed over the surface 102 of the carrier 10.

The electronic component 13 may include the conductive pad 13p adjacent to the surface 131 (such as the active surface). The conductive pad 13p of the electronic component 13 may be electrically connected with the carrier 10 through the electrical contact 13e. The surface 132 (such as the backside surface) of the electronic component 13 may face away from the carrier 10.

Referring to FIGS. 3G and 3H, the structure (or panel assembly) obtained from the operation shown in FIG. 3F may be leveled or flattened. In some arrangements, the leveling operation may be configured for warpage control. For example, the structure (or panel assembly) obtained from the operation in FIG. 3F may be placed on a stage 31. The stage 31 may include nozzles (or chucks) 31v. The nozzles 31v may provide suction force on the structure (or panel assembly) to reduce warpage or deformation.

For instance, the nozzles 31v may include vacuum nozzles. These nozzles 31v may be evacuated by a vacuum pump to reduce the internal pressure, allowing the structure (or panel assembly) to be held in place by the atmospheric pressure exerted by the nozzles 31v.

The heights of the nozzles 31v may be adjustable according to the shape of the structure (or panel assembly) obtained from the operation shown in FIG. 3F. For example, the structure (or panel assembly) is lower in the center and higher on the peripheral portion. The nozzles 31v may be lower in the center and higher on the peripheral portion. For example, the structure (or panel assembly) is lower on the peripheral portion and higher in the center. The nozzles 31v may be lower on the peripheral portion and higher in the center.

The nozzles 31v may contact the structure (or panel assembly). The nozzles 31v may include a flexible material (such as rubber). The nozzles 31v may adhere to the structure (or panel assembly) and pull it down to flatten it. Since the heights of the nozzles 31v correspond to the degree of curvature of the structure (or panel assembly), they provide an even suction force, allowing the structure (or panel assembly) to be uniformly flattened.

The structure obtained from the operation shown in FIG. 3H may be a leveled or flattened panel assembly.

Referring to FIG. 3I, a singulation may be performed to separate out individual strips. The singulation may be performed by, for example, using a dicing saw, laser or other appropriate cutting techniques. For example, the flattened panel assembly obtained from the operation shown in FIG. 3H may be separated or divided into a plurality of strips.

In some arrangements, the singulation may be referred to as a first singulation. In some arrangements, the singulation may be configured for warpage control. In some arrangements, the singulation may promote uniform stress distribution and reduce the risk of deformation. In some arrangements, the singulation may create a stable, planar foundation essential for the subsequent molding operation (such as the operation shown in FIG. 3K).

FIG. 3I′ illustrates a top view of the structure shown in FIG. 3I. In some arrangements, FIG. 3I provides a cross-sectional view of the structure cut along the line AA′ in FIG. 3I′. The flattened panel assembly may be separated or divided along a plurality of columns. In some arrangements, the flattened panel assembly may be separated along the cutting area having the distance a1.

Since each of the strip units is subjected to similar or identical processes in the manufacturing method, for convenience, only an exemplary strip unit is illustrated and described in the following description.

The structure obtained from the operation shown in FIG. 3I may be a strip assembly. The strip assembly may include one or more electronic components 11 embedded, covered, or encapsulated in the encapsulant 12. One or more carriers 10 and one or more electronic components 13 may be disposed over the strip assembly. The carriers 10 may be spaced apart by the cutting area having the distance a2.

Referring to FIG. 3J, the connection element 15 may be formed by wire bonding, electroplating, photolithography, bumping, or other suitable operations.

Referring to FIG. 3K, the encapsulant 14 may be disposed over the encapsulant 12 to cover the one or more carriers 10. The encapsulant 14 may cover, surround, or encapsulate the carrier 10, the electronic component 13, and/or the connection element 15.

In some arrangements, the encapsulant 14 may be disposed over the cutting area having the distance a2. For example, the encapsulant 14 may cover the cutting area having the distance a2. For example, the encapsulant 14 may cover the encapsulant 12 in the cutting area.

The surface 141 of the encapsulant 14 may contact (such as directly contact) the encapsulant 12. The surface 141 of the encapsulant 14 may be substantially aligned or coplanar with the surface 101 of the carrier 10. In some arrangements, an interface or an intersurface, labeled “141,” of the encapsulant 14 and the encapsulant 12 may be substantially aligned or coplanar with the surface 101 of the carrier 10. The surface 142′ of the encapsulant 14 may face away from the carrier 10. In some arrangements, the surface 142′ of the encapsulant 14 may be the farthest surface from the carrier 10.

In some arrangements, the encapsulant 14 may be formed by molding, such as by printing, compression molding, transfer molding, liquid encapsulant molding, vacuum lamination, spin coating, or other suitable processes.

In some arrangements, the operation shown in FIG. 3K may be referred to as a second molding operation. The structure obtained from the operation shown in FIG. 3K may be a strip assembly. The strip assembly may include one or more electronic components 11, one or more carriers 10, and one or more electronic components 13 embedded, covered, or encapsulated in the encapsulants 12 and 14. The carriers 10 may be spaced apart by the cutting area having the distance a2.

Referring to FIG. 3L, a planarization operation or a grinding operation may be performed to remove a portion of the encapsulant 14 to expose the end 15t of the connection element 15. For example, the end 15t of the connection element 15 may be exposed by the surface 142 of the encapsulant 14.

The planarization operation or grinding operation may include an abrasive machining process that uses a grinding wheel or grinder, a chemical mechanical planarization (CMP) process, an etching process, or a laser direct ablation (LDA) process.

Referring to FIG. 3M, the conductive pad 14p and the electrical contact 14e may be disposed over the surface 142 of the encapsulant 14 for providing electrical connections between the electronic device 1 and an external device (e.g., a PCB, another electronic device, an electronic module, and so on).

Referring to FIG. 3N, a singulation may be performed to separate out individual electronic devices. The singulation may be performed by, for example, using a dicing saw, laser or other appropriate cutting techniques. For example, the strip assembly obtained from the operation shown in FIG. 3L may be separated or divided into a plurality of electronic devices.

The encapsulants 12 and 14 may be cut in the same singulation operation.

FIG. 3N′ illustrates a top view of the structure shown in FIG. 3N. In some arrangements, FIG. 3N provides a cross-sectional view of the structure cut along the line BB′ in FIG. 3N′. The line BB′ may be substantially perpendicular to the line AA′ in the previous figures. In some arrangements, the strip assembly may be separated along the cutting area having the distance a2. In some arrangements, the singulation shown in FIGS. 3N and 3N′ may be referred to as a second singulation.

According to some embodiments of the present disclosure, the present disclosure provides a manufacturing process that includes warpage control. For example, the leveling operation shown in FIGS. 3G and 3H, as well as the first singulation shown in FIGS. 3I and 3I′, are configured for warpage control. The implementation of a two-step singulation process significantly enhances warpage management in manufacturing. In the first singulation, the panel assembly is divided into strips, promoting uniform stress distribution and reducing the risk of deformation. This first singulation also creates a stable, planar foundation that is essential for the subsequent molding process. Consequently, the overall quality and precision of the final product are improved, resulting in enhanced performance and reliability in its intended application.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of arrangements of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific arrangements thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other arrangements of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A method of manufacturing an electronic device, comprising:
providing a panel assembly including a plurality of first electronic components;
dividing the panel assembly into a plurality of strips;
forming a first encapsulant over one of the plurality of strips; and
dividing the one of the plurality of strips into a plurality of electronic devices.

2. The method of claim 1, wherein providing the panel assembly comprises:
providing a temporary carrier;
disposing the plurality of first electronic components over the temporary carrier; and
forming a second encapsulant over the temporary carrier to cover the plurality of first electronic components.

3. The method of claim 2, wherein the plurality of first electronic components are arranged in an M×N array, and dividing the panel assembly into the plurality of strips comprises:
dividing the panel assembly into M strips, with each strip containing N first electronic components.

4. The method of claim 3, wherein dividing the one of the plurality of strips into the plurality of electronic devices comprises:
dividing the one of the plurality of strips into N first electronic components.

5. The method of claim 2, further comprising:
removing a portion of the second encapsulant; and
removing the temporary carrier to expose backside surfaces of the plurality of first electronic components.

6. The method of claim 2, wherein forming the first encapsulant over one of the plurality of strips comprises:
contacting the second encapsulant with the first encapsulant.

7. The method of claim 1, further comprising:
disposing a plurality of interconnection structures over the panel assembly, wherein the plurality of interconnection structures are spaced apart by a distance; and
disposing a plurality of second electronic components over the panel assembly.

8. The method of claim 7, wherein forming the first encapsulant over one of the plurality of strips comprises:
covering the plurality of second electronic components with the first encapsulant.

9. A method of manufacturing an electronic device, comprising:
providing a first electronic component;
forming an interconnection structure over the first electronic component;
forming a cutting area adjacent to the interconnection structure; and
forming a first encapsulant over the cutting area.

10. The method of claim 9, further comprising:
forming a second encapsulant over the first electronic component; and
removing a portion of the second encapsulant to expose a conductive pad for electrically connecting the interconnection structure.

11. The method of claim 10, wherein forming the cutting area adjacent to the interconnection structure comprises:
covering a portion of the second encapsulant with the interconnection structure and exposing another portion of the second encapsulant to form the cutting area.

12. The method of claim 11, wherein forming the first encapsulant over the cutting area comprises:
covering the second encapsulant in the cutting area with the first encapsulant.

13. A method of manufacturing an electronic device, comprising:
providing a panel assembly including a plurality of first electronic components;
obtaining at least one strip from the panel assembly for warpage control;
forming a first encapsulant over the at least one strip; and
obtaining at least one electronic device from the at least one strip.

14. The method of claim 13, wherein the panel assembly includes a second encapsulant encapsulating the plurality of first electronic components.

15. The method of claim 14, further comprising:
disposing an interconnection structure over the panel assembly, wherein a portion of the second encapsulant is exposed from the interconnection structure and is configured as a cutting area.

16. The method of claim 15, wherein obtaining the at least one strip from the panel assembly for warpage control comprises:
cutting the second encapsulant through the cutting area.

17. The method of claim 15, further comprising:
disposing a second electronic component over the interconnection structure, wherein one of the plurality of first electronic components, the second electronic component, and the interconnection structure are at least partially overlapped.

18. The method of claim 13, further comprising:
leveling the panel assembly by providing a suction force on the panel assembly.

19. The method of claim 13, further comprising:
forming a connection element over the at least one strip; and
covering the connection element with the first encapsulant.

20. The method of claim 19, further comprising:
forming an electrical contact over the first encapsulant to electrically connect the connection element.
